(19) United States
(12) Patent Application Publication
(10) Pub. No.: US 2026/0188393 A1
(43) Pub. Date: Jul. 2, 2026

(54) CALIBRATION CIRCUITS, CALIBRATION METHODS THEREOF, MEMORY DEVICES AND MEMORY SYSTEMS

(71) Applicant: Yangtze Memory Technologies Co., Ltd., Wuhan (CN)

(72) Inventors: Lin Miao, Wuhan (CN); Dong He, Wuhan (CN)

(21) Appl. No.: 19/290,049

(22) Filed: Aug. 4, 2025

(30) Foreign Application Priority Data
Dec. 31, 2024 (CN) 202411982115.5

(51) Int. Cl. G11C 16/30

(52) U.S. Cl. CPC G11C 16/30

(57) ABSTRACT

The examples of the present disclosure provide calibration circuits and calibration methods thereof, memory devices and memory systems, relate to the field of semiconductor technology, can improve the accuracy and efficiency of the calibration and reduce the time consumption of calibration operation on data interaction. The calibration circuit includes a calibration power management circuit and a calibration sub-circuit. The calibration power management circuit is configured to receive a power supply voltage signal and output a calibrated power supply voltage signal based on the power supply voltage signal. The calibration sub-circuit is coupled to the calibration power management circuit and is configured to generate an impedance calibration code using the calibrated power supply voltage signal in response to a first driving signal.

### CROSS-REFERENCE TO RELATED APPLICATIONS

This application claims priority to and the benefit of Chinese Patent Application 202411982115.5, filed on Dec. 31, 2024, which is hereby incorporated by reference in its entirety.

### TECHNICAL FIELD

Examples of the present disclosure relate to the field of semiconductor technologies, and in particular, to calibration circuits, calibration methods thereof, memory devices, and memory systems.

### BACKGROUND

During data read and write operations performed by a memory device, data is exchanged with an external device (e.g., a memory controller) through input-output circuit.

### BRIEF DESCRIPTION OF DRAWINGS

In the drawings, like reference numbers may describe similar components in different views. Like reference numbers with different letter suffixes may represent different examples of similar components. The drawings generally illustrate various examples discussed herein by way of example and not limitation.

FIG. 1 is a first schematic structural diagram of a calibration circuit according to an example of the present disclosure;

FIG. 2 is a second schematic structural diagram of a calibration circuit according to an example of the present disclosure;

FIG. 3 is a third schematic structural diagram of a calibration circuit according to an example of the present disclosure;

FIG. 4 is a fourth schematic structural diagram of a calibration circuit according to an example of the present disclosure;

FIG. 5 is a fifth schematic structural diagram of a calibration circuit according to an example of the present disclosure;

FIG. 6 is a sixth schematic structural diagram of a calibration circuit according to an example of the present disclosure;

FIG. 7 is a first schematic flowchart of a calibration method of a calibration circuit according to an example of the present disclosure;

FIG. 8 is a second schematic flowchart of a calibration method of a calibration circuit according to an example of the present disclosure;

FIG. 9 is a third schematic flowchart of a calibration method of a calibration circuit according to an example of the present disclosure;

FIG. 10 is a fourth schematic flowchart of a calibration method of a calibration circuit according to an example of the present disclosure;

FIG. 11 is a schematic structural diagram of a memory device according to an example of the present disclosure;

FIG. 12 is a schematic structural diagram of a peripheral circuit of a memory device according to an example of the present disclosure;

FIG. 13 is a schematic structural diagram of a memory system according to an example of the present disclosure;

FIG. 14 is a schematic structural diagram of an electronic device according to an example of the present disclosure.

### DETAILED DESCRIPTION

The technical solutions of the present disclosure are further described in detail below with reference to the accompanying drawings and specific examples.

In the examples of the present disclosure, the terms “first”, “second”, and the like are used to distinguish similar objects, and are not used to describe a specific order or a sequential order.

In the examples of the present disclosure, the term “A is in contact with B” includes situations where A is in direct contact with B, or where there are other components inserted between A and B and A is in indirect contact with B.

It should be understood that “some examples” or “some implementations” mentioned throughout the specification means that particular features, structures, or characteristics related to the examples are included in at least one example of the present disclosure. Thus, “in some examples” or “in some implementations” appearing throughout the specification need not necessarily refer to the same example. Further, these particular features, structures, or characteristics may be combined in one or more examples in any suitable manner. It should be understood that, in various examples of the present disclosure, the sequence numbers of the above processes do not mean the order of execution sequences, and an execution sequence of individual process should be determined by a function and an intrinsic logic thereof, and should not constitute any limitation on an implementation of the examples of the present disclosure. The above sequence numbers of the examples of the present disclosure are merely for description, and do not represent the advantages and disadvantages of the examples.

It should be noted that, in this specification, the terms “comprising”, “including”, or any other variant thereof are intended to cover a non-exclusive inclusion, such that a process, method, article, or apparatus that comprises a series of elements comprises not only those elements but also other elements not explicitly listed, or elements inherent to such process, method, article, or apparatus. Without further restriction, the elements defined by the statement “comprise one” do not preclude the presence of additional identical elements in the process, method, article, or apparatus that comprises the element.

It is to be understood that the meaning of “on”, “above”, and “over” in the present disclosure should be interpreted in a broadest manner such that “on” not only indicates its “on” something and there is no intervening feature or layer therebetween (i.e., directly on something), but also comprises the meaning of “on” something and there is intervening feature or layer therebetween.

It should be noted that although the present specification is described in terms of implementations, not every implementation comprises only one independent technical solution, and this description of the specification is merely for the sake of clarity, and the specification should be understood by those skilled in the art as a whole, and the technical solutions in the implementations may also be combined appropriately to form other implementations that can be understood by those skilled in the art.

Semiconductor memory devices may be classified as volatile memory devices and non-volatile memory devices. Volatile memory devices have high read speeds and write speeds. For example, volatile memory devices comprise dynamic random access memory (DRAM) devices and static random access memory (SRAM) devices, among others. For example, non-volatile memory devices comprise read only memory (ROM), flash memory, and NAND memory devices, among others.

Semiconductor memory devices may exchange data with external devices (e.g., memory controllers) through input-output (I/O) circuits.

As the operating speed of the memory device increases, the swing width of the signal transmitted and received between the memory device and the memory controller decreases, and the signal distortion is more easily caused by the impedance mismatch. As the operating speed of the memory device increases, the swing width of signals transmitted and received between the memory device and the memory controller as well as the impedance mismatches tend to cause signal distortion. In some examples, an impedance calibration circuit can be configured for impedance calibration to improve the accuracy of signals transmitted between the memory device and the memory controller. However, in the impedance calibration process, the noise on a power line may affect the accuracy of impedance calibration and can easily increase the time consumption of data interaction.

To address signal distortion issues, impedance calibration circuits may be employed in some examples to perform impedance calibration on the signals transmitted between the memory device and the memory controller, to adjust by using external resistors, so that the termination impedance of the memory device becomes stable independent of variations of process, voltage, and temperature (PVT).

It should be noted that the impedance calibration (Zone Qualifier, ZQ) circuit is configured to improve signal integrity, and calibrate the signal timing in real time by testing the variation in resistance of the internal resistor, so as to optimize the data transmission function. ZQ calibration is an important mechanism to ensure that memory modules maintain optimal performance under different environmental conditions. Through precise resistance calibration, impedance discontinuity in signal transmission can be minimized, thereby improving reliability of data transmission and overall performance of a memory system.

For example, the impedance calibration circuit is coupled to the I/O circuit, can perform output impedance calibration on the output signal sent by the output terminal of the I/O circuit, and perform input impedance calibration on the input signal received by the input terminal of the I/O circuit.

Currently, in the case that a memory system comprises a plurality of memory devices and a memory controller, the plurality of memory devices shares a set of buses and power supplies. In the case of ZQ calibration on at least one memory device, I/O read and write operations of all other memory devices on the bus must be first exited to prevent noise on the power line from affecting the ZQ calibration accuracy of the memory device being calibrated.

Moreover, in the case that the memory system comprises a single memory device and a memory controller, to perform ZQ calibration on a single memory device, I/O read and write operations on the bus still need to be first exited, so as to prevent noise on the power line from affecting the ZQ calibration accuracy of the memory device being calibrated.

The power supply voltage for driving the ZQ calibration circuit is transmitted through the I/O circuit. A charge loss of the power supply voltage for driving the ZQ calibration circuit during the transmission process or the voltage instability caused by the operation of the I/O circuit generates noise, which affects the ZQ calibration accuracy of the memory device being calibrated. That is, the ZQ calibration operation and the I/O read and write operation cannot use the power supply voltage on the power supply line simultaneously, and there is error between the power supply voltage values used by the ZQ calibration operation and the I/O read and write operation.

Therefore, before the ZQ calibration operation is performed, I/O read and write operations of all memory devices on the bus need to be exited, and after the memory device to be tested performs ZQ calibration, the operations prior to calibration are resumed, resulting in the concurrency degree of the I/O read and write operations performed by the plurality of memory devices is reduced, and the use efficiency of the bus is reduced; meanwhile, the time for I/O read and write data is increased, resulting in the memory device achieving I/O read and write data with a delay. Moreover, the accuracy of the calibration by the ZQ calibration circuit under the drive of the power supply transmitted by the I/O circuit is reduced.

In order to solve one or more of the above problems, the present disclosure provides a calibration circuit, a calibration method thereof, a memory device, and a memory system, which can reduce the time consumption of the calibration operation, improve the efficiency of the calibration, and facilitate improving the accuracy of the calibration.

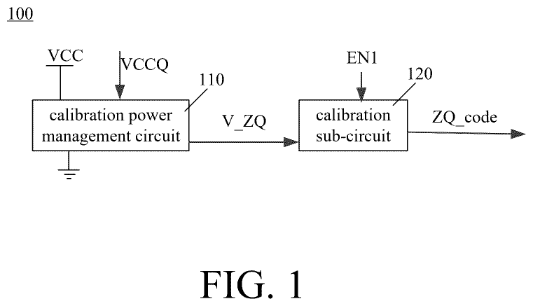

In some examples, as shown in FIG. 1 to FIG. 6, the present disclosure provides a calibration circuit 100, which can perform impedance calibration on data transmitted by a current memory device without exiting an I/O read and write operation of the memory device.

In some examples, as shown in FIG. 1, the calibration circuit 100 comprises a calibration power management circuit 110 and a calibration sub-circuit 120.

The calibration power management circuit 110 is configured to receive the power supply voltage signal VCCQ and output a calibrated power supply voltage signal V_ZQ based on the power supply voltage signal VCCQ.

The calibration sub-circuit 120 is coupled to the calibration power management circuit 110, and is configured to generate an impedance calibration code ZQ_code by using the calibration power voltage signal V_ZQ in response to a first driving signal EN1. For example, the calibration sub-circuit 120 comprises a ZQ impedance calibration circuit.

The above calibration power management circuit 110 receives the power supply voltage signal VCCQ, rather than the received power supply signal transmitted to the calibration circuit 100 by another circuit (for example, an input-output circuit) in some examples, the power supply voltage signal VCCQ of the drive calibration circuit 100 in the present disclosure is not affected by the noise on other signal lines, and in turn the power supply signal (that is, the calibrated power supply voltage signal VCCQ) that drives the calibration sub-circuit 120 to perform the calibration operation does not have an error or has a negligible error, so that the impedance calibration code ZQ_code generated by the calibration sub-circuit 120 by using the calibrated power supply voltage signal V_ZQ is more accurate, and the accuracy of the impedance calibration of the calibration circuit 100 can be improved.

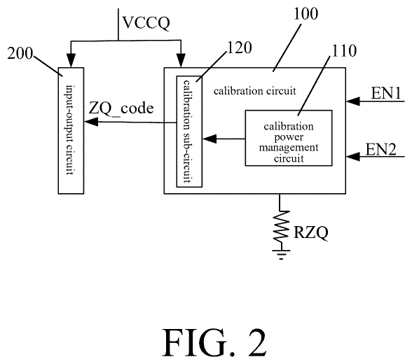

In addition, in some examples, the input-output circuit uses the power supply voltage signal to perform the data interaction operation, the voltage that drives calibration circuit is transmitted by the input-output circuit, and the input-output circuit does not perform data interaction when the calibration circuit performs the calibration operation, the calibration circuit 100 according to the present disclosure directly uses the power supply voltage signal VCCQ, that is, the calibration circuit 100 and the input-output circuit 200 (shown in FIG. 2) according to the present disclosure receive the power supply voltage signal VCCQ respectively, both of the calibration circuit 100 and the input-output circuit 200 are operable to work simultaneously, the work efficiency of the data interaction and calibration can be improved, the time consumption caused by the fact that the calibration circuit 100 and the input-output circuit 200 cannot work simultaneously is reduced, and the efficiency of the data interaction is improved.

It may be understood that the calibration circuit 100 according to the present disclosure may output an impedance calibration code ZQ_code, where the impedance calibration code ZQ_code is a group of binary codes representing the impedance value of the calibrated circuit that needs to be adjusted in the case of the impedance matching with the calibrated circuit (or the load device), and the integrity of signals transmitted by the calibrated circuit is improved. The specific circuit logic of the calibration sub-circuit 120 of the calibration circuit 100 is not limited in the present disclosure, and may be set according to the technologies of the art. For example, the calibration sub-circuit 120 comprises a ZQ impedance calibration circuit.

In some examples, the calibration circuit 100 may further comprise a register to store the impedance calibration code ZQ_code output by the calibration sub-circuit 120, so that the calibrated circuit acquires and utilizes the impedance calibration code ZQ_code.

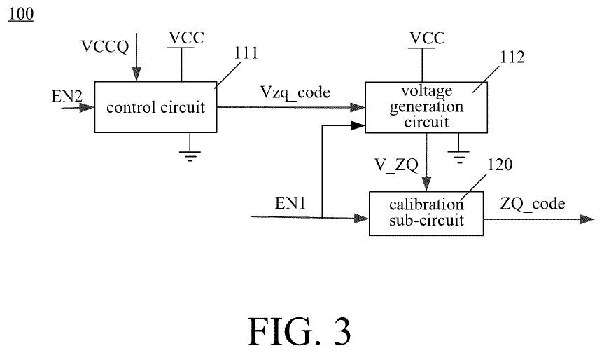

In some examples, as shown in FIG. 3 to FIG. 5, the calibration power management circuit 110 comprises a control circuit 111 and a voltage generation circuit 112.

The control circuit 111 is configured to receive and process the power supply voltage signal VCCQ and then output the voltage calibration code Vzq_code. For example, the control circuit 111 may comprise an analog to digital converter (ADC).

The voltage generation circuit 112 is configured to acquire the voltage calibration code Vzq_code in response to the first driving signal EN1, and output the calibrated power supply voltage signal V_ZQ according to the voltage calibration code Vzq_code.

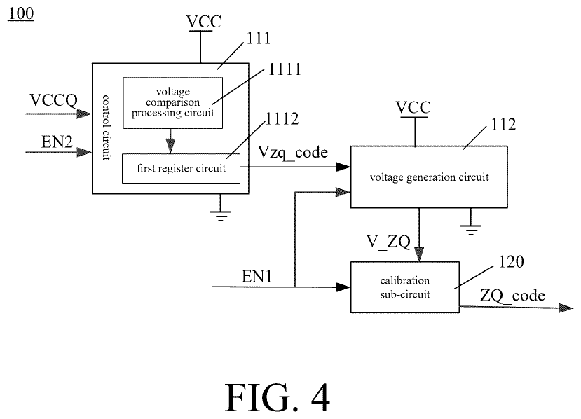

Further, as shown in FIG. 4, the control circuit 111 comprises a voltage comparison processing circuit 1111 and a first register circuit 1112.

The voltage comparison processing circuit 1111 is configured to compare a reference voltage with the power supply voltage signal VCCQ in response to the second driving signal EN2 and output the voltage calibration code Vzq_code.

The first register circuit 1112 is coupled to the voltage comparison processing circuit 1111, and is configured to store the voltage calibration code Vzq_code.

For example, the control circuit 111 may comprise an analog to digital converter (ADC). The analog to digital converter (ADC) comprises a voltage comparison processing circuit 1111 and a first register circuit 1112.

For example, the voltage comparison processing circuit 1111 may comprise a comparator configured to compare a magnitude relationship between the reference voltage and the power supply voltage signal VCCQ, determine a quantization level of the processed power supply voltage signal VCCQ, and determine the voltage calibration code Vzq_code.

For example, the first register circuit 1112 may comprise a register. The first register circuit 1112 may store the voltage calibration code Vzq_code, so that other circuits can acquire the voltage calibration code Vzq_code at other moments in response to the enable signal.

It can be understood that the voltage comparison processing circuit 1111 and the first register circuit 1112 used in the present disclosure functionally reflect the structure of the circuit, and do not limit the number and connection relationship of the electronic components of the voltage comparison processing circuit 1111 and the first register circuit 1112, and may be set according to actual requirements.

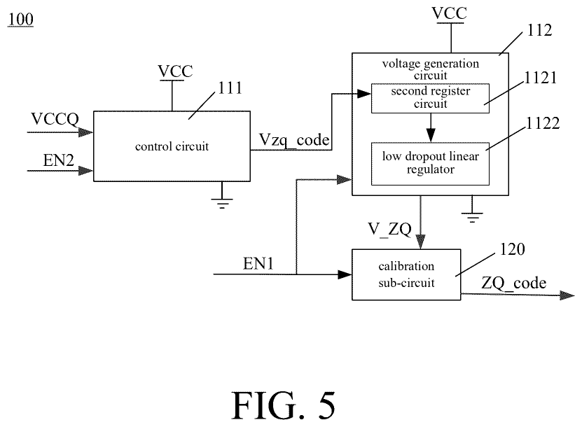

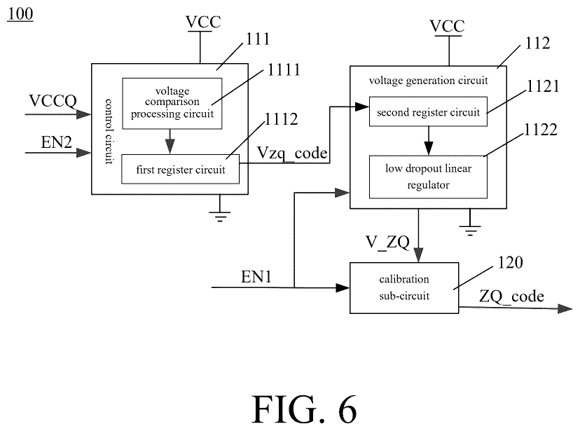

In some examples, as shown in FIG. 5 and FIG. 6, the voltage generation circuit 112 comprises a second register circuit 1121. The second register circuit 1121 is coupled to the first register circuit 1112, and is configured to acquire and store the voltage calibration code Vzq_code in the first register circuit 1112 in response to the first driving signal EN1.

For example, the voltage generation circuit 112 may comprise a low dropout linear regulator (LDO) or a DC-DC regulator (DC-DC) 1122, and a second register circuit 1121. The second register circuit 1121 may comprise a register for storing the voltage calibration code Vzq_code.

For example, as shown in FIG. 6, the second register circuit 1121 is coupled to the low dropout linear regulator (LDO) 1122 and the first register circuit 1112, and is configured to acquire and store the voltage calibration code Vzq_code in the first register circuit 1112 in response to the first driving signal EN1.

The low dropout linear regulator (LDO) 1122 is coupled to the second register circuit 1121. According to the voltage calibration code Vzq_code stored in the second register circuit 1121, the LDO outputs the calibrated power supply voltage signal V_ZQ to the calibration sub-circuit 120 in the power-on condition, and the LDO has a lower noise, which helps to improve the quality of the calibrated power supply voltage signal V_ZQ, and in turn the accuracy of the impedance calibration code ZQ_code output by the calibration sub-circuit 120 is improved, and the accuracy of the impedance calibration of the calibration circuit 100 can be improved.

Base on that the control circuit 111 may comprise an analog to digital converter (ADC); wherein in addition to a voltage comparison processing circuit 1111 (for example, a comparator) and a first register circuit 1112 (for example, a register), the analog to digital converter ADC comprises other circuits such as a counter, an amplifier, and a control logic circuit. And the voltage generation circuit 112 may comprise a low dropout linear regulator (LDO) or a DC-DC regulator (DC-DC) 1122, a second register circuit 1121, these circuits work together to implement analog-to-digital conversion based on the power supply voltage signal VCCQ, and output a calibrated power supply voltage signal V_ZQ that drives the calibration sub-circuit 120.

The present disclosure illustratively provides the circuits related to the control logic of the generation of the calibrated power supply voltage signal V_ZQ that drives the calibration sub-circuit 120, and does not limit to only include these circuits, and may be adjusted according to the technology in the art.

In addition, the following examples reflect the circuit structure of the control logic of the generation of the calibrated power supply voltage signal V_ZQ that drives the calibration sub-circuit 120 from the perspective of the functional implementation of individual circuit in the calibration circuit 100.

In some examples, the voltage comparison processing circuit 1111 is configured to acquire the power supply voltage signal VCCQ at a first preset time interval T1, and respond to the second driving signal EN2 when the difference between the acquired two adjacent power supply voltage signals VCCQ is greater than the first threshold M1.

And/or, the voltage comparison processing circuit 1111 is further configured to acquire the temperature of the calibration circuit 100 at a second preset time interval T2, and respond to the second driving signal EN2 when the variation between two adjacent temperatures is greater than the second threshold M2.

In this way, when the comparison condition with at least one parameter of the first threshold M1 or the second threshold M2 is satisfied, it can respond to the second driving signal EN2 again, which can reduce the influence of the external environment and improve the accuracy of the voltage calibration code Vzq_code.

For example, the first threshold M1 represents a minimum difference between two adjacent power supply voltage signals VCCQ that will affect the voltage calibration code Vzq_code output subsequently. The voltage comparison processing circuit 1111 may acquire the power supply voltage signal VCCQ at a first preset time interval T1, and in the case that the difference between the acquired two adjacent power supply voltage signals VCCQ is greater than the first threshold M1, it is necessary to process the current (i.e., updated) power supply voltage signal VCCQ in response to the second driving signal EN2 again, and output the updated voltage calibration code Vzq_code.

In this way, the probability of errors presented in the voltage calibration code Vzq_code output by the voltage comparison processing circuit 1111 due to instability of the power supply voltage signal VCCQ can be reduced, and the accuracy of the voltage calibration code Vzq_code is improved.

For another example, the second threshold M2 represents a minimum variation of two adjacent temperatures that will affect the voltage calibration code Vzq_code output subsequently. The voltage comparison processing circuit 1111 may acquire the temperature of the calibration circuit 100 at a second preset time interval T2, and in the case that the variation of two adjacent temperatures is greater than the second threshold M2, it is necessary to process the current (i.e., updated) power supply voltage signal VCCQ in response to the second driving signal EN2 again, and output the updated voltage calibration code Vzq_code.

It may be understood that an electronic device for sensing temperature, such as a temperature sensor, a thermistor or the like, can be used to acquire the temperature of the calibration circuit 100, and is coupled to the voltage comparison processing circuit 1111 or as an internal circuit structure of the voltage comparison processing circuit 1111, so that the voltage comparison processing circuit 1111 outputs the voltage calibration code Vzq_code based on the variation of two adjacent temperatures being greater than the second threshold M2. The circuit structure implemented to sense temperature, and the circuit structure in which the voltage comparison processing circuit 1111 output the voltage calibration code Vzq_code based on the variation condition of the sensed temperature, are not limited in the present disclosure, and may be set according to actual requirements.

In this way, the probability of errors presented in the voltage calibration code Vzq_code output by the voltage comparison processing circuit 1111 due to the greater frequency of the temperature variation or the greater temperature difference of the environment in which the calibration circuit 100 is located can be reduced, and the accuracy of the voltage calibration code Vzq_code is improved.

For another example, the voltage comparison processing circuit 1111 may not only acquire the power supply voltage signal VCCQ at a first preset time interval of T1, and in the case that the difference between the acquired two adjacent power supply voltage signals VCCQ is greater than the first threshold M1, it is necessary to process the current (i.e., updated) power supply voltage signal VCCQ in response to the second driving signal EN2 again, and output the updated voltage calibration code Vzq_code.

Moreover, the voltage comparison processing circuit 1111 may further acquire the temperature of the calibration circuit 100 at a second preset time interval T2, and in the case that the variation of two adjacent temperatures is greater than the second threshold M2, it is necessary to process the current (i.e., updated) power supply voltage signal VCCQ again in response to the second driving signal EN2, and output the updated voltage calibration code Vzq_code.

In this way, in a case that both the relationship between the temperature variation of the calibration circuit 100 and the second threshold M2, and the relationship between the power supply voltage signal VCCQ used by the calibration circuit 100 and the first threshold M1 can be compared simultaneously, in order to avoid interleaving of the execution processes of the two logics, which causes to frequently respond to the second driving signal EN2, increase the additional energy consumption, and reduce the work efficiency of the calibration circuit 100, the first preset duration T1 and the second preset duration T2 can be set to be equal. In this way, the results of determining the two logics are combined to further reduce the influence of the external environment, and improve the accuracy of the voltage calibration code Vzq_code.

In some examples, the voltage comparison processing circuit 1111 is further configured to acquire the power supply voltage signal VCCQ when the calibration circuit 100 is powered on, respond to the second driving signal EN2, process the power supply voltage signal VCCQ, and output the voltage calibration code Vzq_code.

For example, with the acquisition of the power supply voltage signal VCCQ when the calibration circuit 100 is powered on, the impedance calibration operation can be performed quickly by using the acquired power supply voltage signal VCCQ in the case that the calibration circuit 100 receives and responds to the second driving signal EN2, the response speed of the calibration circuit 100 can be improved, and the efficiency of the calibration can be improved.

It should be noted that, after the calibration circuit 100 acquires the power supply voltage signal VCCQ at the time of power-on and performs the impedance calibration operation, the calibration circuit 100 may further receive the second driving signal EN2 and perform the next impedance calibration operation in response to the second driving signal EN2. In this case, the voltage value of the power supply voltage signal VCCQ used by the calibration circuit 100 may be the same as or different from the voltage value of the power supply voltage signal VCCQ when the calibration circuit 100 is powered on, and may be set according to the application scenario of the calibration circuit 100.

For example, the voltage value of the power supply voltage signal VCCQ acquired by the calibration circuit 100 is related to the voltage value used and processed by the circuit to be calibrated by the calibration circuit 100, and different circuits may utilize different driving voltage values.

For example, as shown in FIG. 2, the calibration circuit 100 is coupled to the input-output circuit 200, and is configured to calibrate the input impedance and the output impedance of the input-output circuit 200. The voltage value of the power supply voltage signal VCCQ acquired by the calibration circuit 100 is equal to the voltage value that drives the input-output circuit 200. In this way, based on the signal with the same voltage value, the noise influence or loss of the signal in the transmission process can be reduced, and the accuracy of the impedance calibration on the input-output circuit 200 by the calibration circuit 100 can be improved.

In some examples, as shown in FIG. 2, the calibration sub-circuit 120 is coupled to the input-output circuit 200, and is configured to output impedance calibration code ZQ_code to the input-output circuit 200 in response to the first driving signal EN1 and calibrate the input impedance and the output impedance of the input-output circuit 200.

If the calibration circuit 100 is to be set to perform impedance calibration on another circuit other than the input-output circuit 200, considering that the input-output circuit 200 is an interface circuit for data interaction between the memory device and the memory controller, in the case that the voltage value of the power supply voltage signal VCCQ acquired by the calibration circuit 100 is set to be equal to the voltage value that drives the input-output circuit 200, the voltage used and processed by the calibration circuit 100 and another circuit other than the input-output circuit 200 may be adjusted to be equal based on a circuit with an adjustable voltage (for example, a reference resistor) within the memory device, and the circuit logic and circuit structure are not limited in the present disclosure, and may be set as desired.

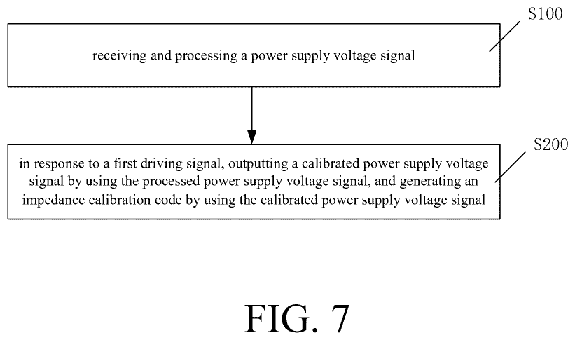

Based on the circuit structure of the above calibration circuit 100, as shown in FIG. 7 to FIG. 10, the present disclosure provides a calibration method of the calibration circuit 100.

In some examples, as shown in FIG. 7, the calibration method comprises S100 and S200.

S100: receiving and processing a power supply voltage signal VCCQ.

For example, as shown in FIG. 1, the calibration power management circuit 110 receives and processes the power supply voltage signal VCCQ.

S200: in response to a first driving signal EN1, outputting a calibrated power supply voltage signal V_ZQ by using the processed power supply voltage signal VCCQ, and generating an impedance calibration code ZQ_code by using the calibration power voltage signal V_ZQ.

For example, for the circuit structure as shown in FIG. 1, the calibration power management circuit 110 outputs the calibrated power supply voltage signal V_ZQ by using the processed power supply voltage signal VCCQ (for example, the voltage calibration code Vzq_code mentioned in the following example) in response to the first driving signal EN1; and the calibration sub-circuit 120 generates the impedance calibration code ZQ_code by using the calibration power voltage signal V_ZQ.

In this way, based on that the calibration power management circuit 110 receives the power supply voltage signal VCCQ, rather than the received power supply signal transmitted to the calibration circuit 100 by another circuit (for example, an input-output circuit) in some examples, the power supply voltage signal VCCQ that drives the calibration circuit 100 in the present disclosure is not affected by the noise on other signal lines, and in turn the power supply signal (that is, the calibrated power supply voltage signal VCCQ) that drives the calibration sub-circuit 120 to perform the calibration operation does not have an error or has a negligible error, so that the impedance calibration code ZQ_code generated by the calibration sub-circuit 120 using the calibrated power supply voltage signal V_ZQ is more accurate, and the accuracy of the impedance calibration of the calibration circuit 100 can be improved.

In addition, in some examples, the input-output circuit uses the power supply voltage signal to perform the data interaction operation, the voltage that drives calibration circuit is transmitted by the input-output circuit, and the input-output circuit does not perform data interaction when the calibration circuit performs the calibration operation, the calibration circuit 100 according to the present disclosure directly uses the power supply voltage signal VCCQ, that is, the calibration circuit 100 and the input-output circuit 200 (shown in FIG. 2) according to the present disclosure receive the power supply voltage signal VCCQ respectively, both of the calibration circuit 100 and the input-output circuit 200 are operable to work simultaneously, the work efficiency of the data interaction and calibration can be improved, the time consumption caused by the fact that the calibration circuit 100 and the input-output circuit 200 cannot work simultaneously is reduced, and the efficiency of the data interaction is improved.

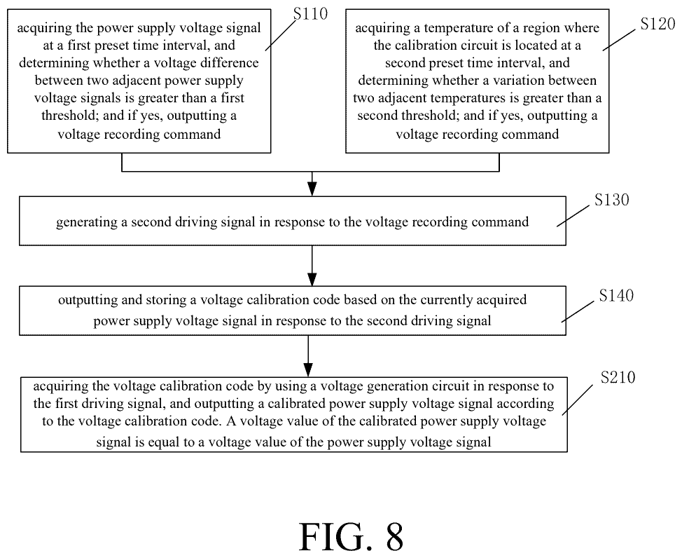

In some examples, as shown in FIG. 8, the above operation S100: the receiving and processing the power supply voltage signal comprises at least one of S110 and S120, S130, S140.

S110: acquiring the power supply voltage signal VCCQ at a first preset time interval T1, and determining whether a voltage difference between two adjacent power supply voltage signals VCCQ is greater than a first threshold M1; and if yes, outputting a voltage recording command V_set.

For example, the first threshold M1 represents a minimum difference between two adjacent power supply voltage signals VCCQ that will affect the voltage calibration code Vzq_code output subsequently.

The voltage comparison processing circuit 1111 may acquire the power supply voltage signal VCCQ at a first preset time interval T1, and in the case that the difference between the acquired two adjacent power supply voltage signals VCCQ is greater than the first threshold M1, the voltage recording command V_set is outputted.

It should be noted that the voltage recording command V_set may be an instruction provided by another control circuit, and the circuit for generating the voltage recording command V_set may be a part of the calibration circuit 100 or an external circuit coupled to the calibration circuit 100, which is not limited in the examples according to the present disclosure.

S120: acquiring temperature of a region where the calibration circuit 100 is located at a second preset time interval T2, and determining whether a variation between two adjacent temperatures is greater than a second threshold M2; and if yes, outputting a voltage recording command V_set.

For example, the second threshold M2 represents a minimum variation of two adjacent temperatures that will affect the voltage calibration code Vzq_code output subsequently. The voltage comparison processing circuit 1111 may acquire the temperature of the calibration circuit 100 at a second preset time interval T2, and in the case that the variation of two adjacent temperatures is greater than the second threshold M2, a voltage recording command V_set is outputted.

For example, an electronic device for sensing temperature, such as a temperature sensor, a thermistor or the like, can be used to acquire the temperature of the calibration circuit 100, and is coupled to the voltage comparison processing circuit 1111 or as an internal circuit structure of the voltage comparison processing circuit 1111, so that the voltage comparison processing circuit 1111 outputs the voltage recording command V_set based on the variation of the two adjacent temperatures being greater than the second threshold M2.

The circuit structure implemented to sense temperature, and the circuit structure in which the voltage comparison processing circuit 1111 output the voltage calibration code Vzq_code based on the variation condition of the sensed temperature, are not limited in the present disclosure, and may be set according to actual requirements.

S130: generating a second driving signal EN2 in response to the voltage recording command V_set.

For example, in addition to the control circuit 111, the calibration power management circuit 110 in the calibration circuit 100 comprises other circuit structures that can generate the second driving signal EN2 in response to the voltage recording command V_set. In other words, other circuits may be triggered to generate the second driving signal EN2 based on the condition that the voltage recording command V_set is generated. It can be understood that the circuit structure for generating the second driving signal EN2 is set in the peripheral circuit of the memory device in some examples, the circuit structure for generating the second driving signal EN2 is not limited in the present disclosure, and does not affect the execution of the method for processing the power supply voltage signal VCCQ based on the second driving signal EN2 in the present disclosure.

S140: in response to the second driving signal EN2, outputting and storing the voltage calibration code Vzq_code based on the currently acquired power supply voltage signal VCCQ.

For example, in combination with the above operation S110 and operation S120, in both case where the second driving signal EN2 may be generated or triggered to generate, the condition under which the voltage comparison processing circuit 1111 of the control circuit 111 may perform the comparison processing operation in response to the second driving signal EN2 is provided. That is, even if the other circuits which run separately generate a signal with function similar to that of the second driving signal EN2, the voltage comparison processing circuit 1111 processes the currently acquired power supply voltage signal VCCQ in response to the second driving signal EN2, outputs and stores the voltage calibration code Vzq_code, only in the case that at least one of the above operation S110 and operation S120 is satisfied.

For example, in a process in which the voltage comparison processing circuit 1111 is performing the operation, in the case that at least one of the above operation S110 and operation S120 is satisfied, the drift of the power supply voltage signal VCCQ and the interference resulting from generating a signal with function similar to that of the second driving signal EN2 by the other circuits which run separately can be reduced, so that the voltage comparison processing circuit 1111 may stably perform the current operation, output and store the voltage calibration code Vzq_code, and would not respond to the signal with function similar to that of the second driving signal EN2. Based on the moment at which the signal with function similar to that of the second driving signal EN2 is generated, the voltage comparison processing circuit 1111 does not re-acquire and process the power supply voltage signal VCCQ, and can further exclude the interference caused by other circuits or environments.

For another example, if the voltage comparison processing circuit 1111 is in an idle state, there are other circuits separately running, and after at least one of the above operation S110 and operation S120 is satisfied, generating a signal with function similar to that of the second driving signal EN2, the voltage comparison processing circuit 1111 may also respond to the signal with function similar to that of the second driving signal EN2, and output and store the voltage calibration code Vzq_code based on the currently acquired power supply voltage signal VCCQ.

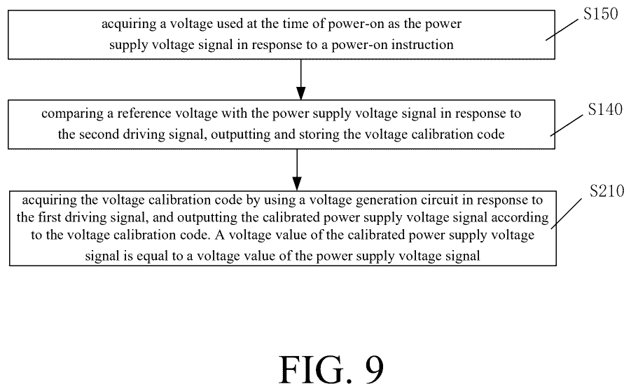

In some other examples, as shown in FIG. 9, the above operation S100: the receiving and processing the power supply voltage signal VCCQ comprises S150 and S160.

S150: acquiring a voltage used at the time of power-on as the power supply voltage signal VCCQ in response to a power-on instruction.

For example, when the calibration circuit 100 is powered on, the control circuit 111 quickly acquires the voltage used at the time of power-on as the power supply voltage signal VCCQ.

S160: in response to the second driving signal EN2, comparing the reference voltage with the power supply voltage signal VCCQ, and outputting and storing the voltage calibration code Vzq_code.

For example, when the calibration circuit 100 is powered on, the calibration circuit 100 may perform a calibration operation immediately based on the power supply voltage signal VCCQ at the time of power-on. In this case, the voltage comparison processing circuit 1111 compares the reference voltage with the power supply voltage signal VCCQ in response to the second driving signal EN2, outputs and stores the voltage calibration code Vzq_code.

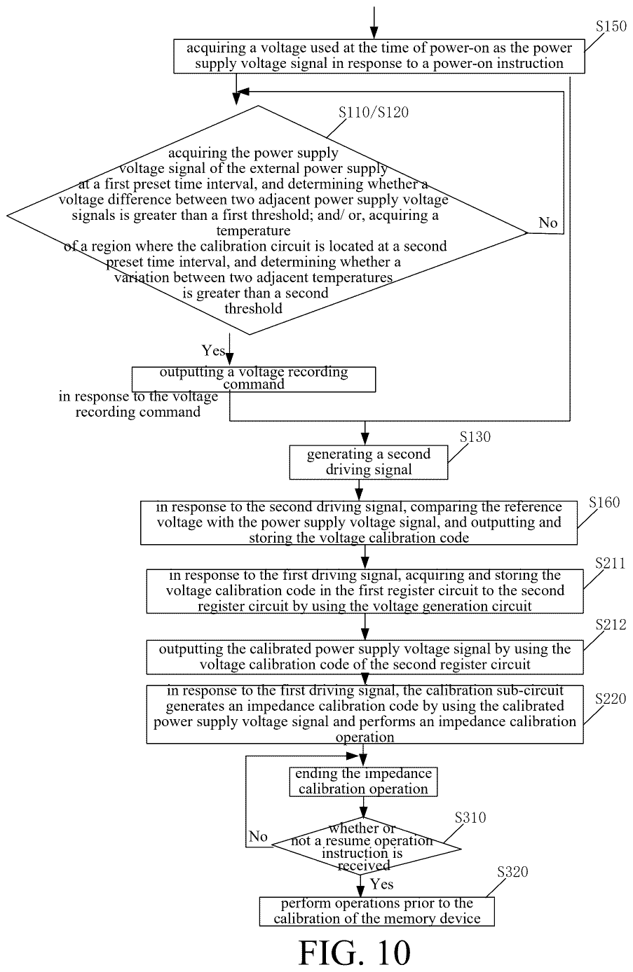

It may be understood that when the calibration circuit 100 is powered on, the second driving signal EN2 that drives the voltage comparison processing circuit 1111 to process the power supply voltage signal VCCQ may be a preset instruction corresponding to a power-on operation, or may be generated by another circuit (for example, as shown in FIG. 10, the second driving signal EN2 may be generated based on at least one of operations S110 and S120 and based on operation S130), which is not limited in the examples according to the present disclosure.

The at least one of above operation S110 and operation S120, operation S130 and operation S140 serve as a logic of the calibration circuit 100 for performing the calibration operation, and the above operation S150 and operation S160 serve as another logic of the calibration circuit 100 for performing the calibration operation, both of the two logics do not conflict and may exist in the memory device at the same time.

In some examples, as shown in FIG. 8 and FIG. 9, the above operation S200: outputting the calibrated power supply voltage signal V_ZQ by using the processed power supply voltage signal VCCQ in response to the first driving signal EN1 comprises S210.

S210: acquiring the voltage calibration code Vzq_code by using a voltage generation circuit 112 in response to the first driving signal EN1, and outputting the calibrated power supply voltage signal V_ZQ according to the voltage calibration code Vzq_code.

The voltage value of the calibrated power supply voltage signal V_ZQ is equal to the voltage value of the power supply voltage signal VCCQ.

In some examples, the voltage that drives the calibration circuit is transmitted by the input-output circuit, and the voltage that drives the calibration circuit is different from the voltage that drives the input-output circuit due to factors such as charge loss, the calibration circuit 100 according to the present disclosure directly utilizes the power supply voltage signal VCCQ, that is, the calibration circuit 100 and the input-output circuit 200 according to the present disclosure receive the power supply voltage signal VCCQ respectively, the voltage value of the calibrated power supply voltage signal V_ZQ is equal to the voltage value of the power supply voltage signal VCCQ, and there is no error or negligible error, so that the impedance calibration code ZQ_code generated by the calibration sub-circuit 120 using the calibrated power supply voltage signal V_ZQ is more accurate, and the accuracy of the impedance calibration of the calibration circuit 100 can be improved.

Taking the structure of the calibration circuit 100 shown in FIG. 6 as an example, different situations that may exist in the process of performing one calibration are illustrated in conjunction with FIG. 8 to FIG. 10 to reflect the execution logic of the calibration method.

In some examples, as shown in FIG. 10, the above operation S200 comprises S210 (referring to FIG. 8 and FIG. 9) and S220, the operation S210 comprises: S211 and S212.

S211: in response to the first driving signal EN1, acquiring and storing the voltage calibration code Vzq_code in the first register circuit 1112 to the second register circuit 1121 (referring to FIG. 5 and FIG. 6) by using the voltage generation circuit 112.

It may be understood that the first driving signal EN1 may be generated by other circuits, and the logic of the generation of the first driving signal EN1 is not limited in the present disclosure, and the frequency and the number of the generation of the first driving signal EN1 are not limited in the present disclosure, that is, the frequencies and numbers of the generation of the first driving signal EN1 and the second driving signal EN2 are not in one-to-one correspondence.

The calibration circuit 100 may perform a calibration operation in response to the first driving signal EN1. The voltage calibration code Vzq_code in the first register circuit 1112 needs to be acquired and stored to the second register circuit 1121 by using the voltage generation circuit 112. Even if there are a plurality of second driving signals EN2, in the case that the control circuit 111 frequently processes the received power supply voltage signal VCCQ and outputs a plurality of voltage calibration codes Vzq_code, in the enabling process of the current first driving signal EN1, the voltage calibration code Vzq_code stored in the second register circuit 1121 is stable.

S212: outputting the calibrated power supply voltage signal V_ZQ by using the voltage calibration code Vzq_code of the second register circuit 1121.

For example, in the case where both the voltage generation circuit 112 and the calibration sub-circuit 120 perform respective operations in response to the same first driving signal EN1, the voltage generation circuit 112 may acquire the voltage calibration code Vzq_code in the first register circuit 1112 and store the voltage calibration code Vzq_code to the second register circuit 1121. In this way, the second register circuit 1121 refreshes the voltage calibration code Vzq_code only in response to the first driving signal EN1, ensuring that the voltage generation circuit 112 can perform an operation based on a stable voltage calibration code Vzq_code.

In this way, a stable calibrated power supply voltage signal V_ZQ can be output by using the voltage calibration code Vzq_code of the second register circuit 1121.

S220: in response to the first driving signal EN1, the calibration sub-circuit 120 generates an impedance calibration code ZQ_code by using the calibrated power supply voltage signal V_ZQ and performs an impedance calibration operation.

For example, in the case that the voltage generation circuit 112 and the calibration sub-circuit 120 perform respective operations in response to the same first driving signal EN1, the calibration sub-circuit 120 can perform a calibration operation based on the stable calibrated power supply voltage signal V_ZQ output by the voltage generation circuit 112, thereby improving the reliability of the calibration circuit 100.

In some examples, during an impedance calibration operation performed by the calibration sub-circuit 120, the calibration power management circuit 110 updates the voltage calibration code Vzq_code stored in the first register circuit 1112 of the control circuit 111 in response to the plurality of second drive signals EN2, respectively.

It may be understood that the first driving signal EN1 and the second driving signal EN2 may be generated by other different circuits, which is not limited in the present disclosure, and the frequencies and the numbers of the generation of the first driving signal EN1 and the second driving signal EN2 are not limited in the present disclosure, that is, the frequencies and numbers of the generation of the first driving signal EN1 and the second driving signal EN2 are not in one-to-one correspondence.

For example, in the case that the above operation S110 and operation S120 are satisfied, the calibration power management circuit 110 updates the voltage calibration code Vzq_code stored in the first register circuit 1112 of the control circuit 111 in response to the plurality of second drive signals EN2, respectively.

During the process of updating the voltage calibration code Vzq_code stored in the first register circuit 1112 of the control circuit 111, the voltage generation circuit 112 may acquire and store the voltage calibration code Vzq_code to the second register circuit 1121 according to the generation condition of the first driving signal EN1, and generate the calibrated power supply voltage signal V_ZQ based on the voltage calibration code Vzq_code of the second register circuit 1121. Then, the calibration sub-circuit 120 generates the impedance calibration code ZQ_code by using the calibrated power supply voltage signal V_ZQ.

In some examples, the calibration method further comprises: acquiring, by the calibration sub-circuit 120, the current first driving signal EN1 based on an ending of the previous impedance calibration operation, and generating an impedance calibration code Vzq_code of a current operation in response to the current first driving signal EN1.

It may be understood that the first driving signal EN1 may be generated by other circuits, and the logic of the generation of the first driving signal EN1 is not limited in the present disclosure, and the frequency and the number of the generation of the first driving signal EN1 are not limited in the present disclosure, that is, when the calibration circuit 100 performs the calibration operation based on one first driving signal EN1, there may be other generated first driving signals EN1.

For example, in the operation S220 as shown in FIG. 10, based on the ending of the previous impedance calibration operation performed by the calibration circuit 100, the calibration sub-circuit 120 acquires the current first driving signal EN1, and generates the impedance calibration code ZQ_code of the current operation in response to the current first driving signal EN1.

The ending of the previous impedance calibration operation may be determined by other circuits, or the calibration circuit 100 may generate an instruction information to indicate that the calibration operation has ended after performing the calibration operation. This is not limited in the present disclosure, and may be set according to actual needs.

In some examples, as shown in FIG. 10, the calibration method further comprises: S310 and S320.

S310: based on the ending of the impedance calibration operation, it is determined whether or not a resume operation instruction is received. For example, if a resume operation instruction is not received, there may be an idle time period after the calibration circuit 100 ends the operation. If a resume operation command is received, subsequent operations can be performed.

S320: continuing to perform operations prior to the calibration of the memory device in response to a resume operation instruction.

For example, based on the ending of the impedance calibration operation, other circuit can generate a resume operation instruction after determining that the calibration operation has ended, or the calibration circuit 100 may automatically trigger the resume operation instruction after performing the calibration operation, and then continue to perform the operation (for example, read data or write data) prior to the calibration of the memory device.

In some examples, the memory device comprises a plurality of memory devices, each of the memory devices comprising the calibration circuit 100 and the input-output circuit 200 that acquire a power supply voltage signal VCCQ of an external power supply from different voltage receiving terminals.

The calibration method further comprises: performing, by the plurality of memory devices, input impedance calibration or output impedance calibration of the plurality of input-output circuits 200 by using the calibrated power supply voltage signal V_ZQ simultaneously in response to one of the first driving signals EN1 respectively. The input-output circuit 200 and the calibration circuit 100 are operable to work simultaneously.

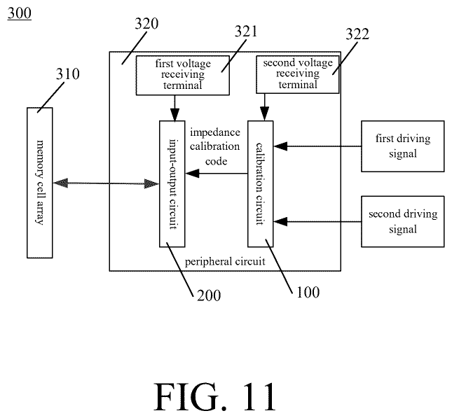

For example, as shown in FIG. 2, a memory device 300 (see FIG. 11) comprises a calibration circuit 100 and an input-output circuit 200. While performing data interaction through the input-output circuit 200, the memory device 300 may perform input impedance calibration or output impedance calibration on the input-output circuit 200 in response to the first driving signal EN1 through the calibration circuit 100.

In the case that the plurality of memory devices 300 can work simultaneously, the plurality of memory devices 300 perform input impedance calibration or output impedance calibration of the plurality of input-output circuits 200 by using the calibrated power supply voltage signal V_ZQ simultaneously in response to one of the first driving signals EN1, respectively, so that the speed of the data interaction can be significantly increased.

Moreover, at least one of the input-output circuit 200 and the calibration circuit 100 in different memory devices 300 are operable to work simultaneously, so that the time consumption of the calibration operation on data interaction can be further reduced.

In some examples, as shown in FIG. 11, the present disclosure provides a memory device 300. For example, the memory device 300 may comprise, but is not limited to, one or more of a NAND flash memory, a vertical NAND flash memory, a NOR flash memory, a dynamic random access memory (DRAM), a ferroelectric random access memory (FRAM), a magnetic random access memory (MRAM), a phase change random access memory (PCRAM), a resistive random access memory (RRAM), a nano random access memory (NRAM), or the like.

Based on the above description, the present disclosure takes the memory device 300 being a semiconductor memory, for example, a solid state electronic device (such as a NAND type memory) for storing data information made by a semiconductor integrated circuit process, as an example to illustrate the following examples. Subsequent examples of the present disclosure do not limit the internal structure of the memory device 300.

In some examples, the above memory device 300 may comprise a memory cell array 310, a peripheral circuit 320 coupled to the memory cell array 310 and the like.

In some examples, as shown in FIG. 11, the memory cell array 310 may be a NAND memory cell array or a DRAM memory cell array. For example, the memory cell array 310 is a circuit structure arranged in an array of NAND memory strings. Each NAND memory string extends vertically on the substrate. For example, each NAND memory string may comprise a plurality of memory cells coupled in series and stacked vertically. Each memory cell may comprise a transistor. For another example, the memory cell array 310 is a circuit structure arranged in an array of DRAM memory cells. Each DRAM memory cell may comprise a transistor and a capacitor.

For example, each memory cell in the memory cell array 310 may be a floating gate type memory cell comprising a floating gate transistor, or a charge trapping type memory cell comprising a charge trapping transistor. This is not limited in the present disclosure.

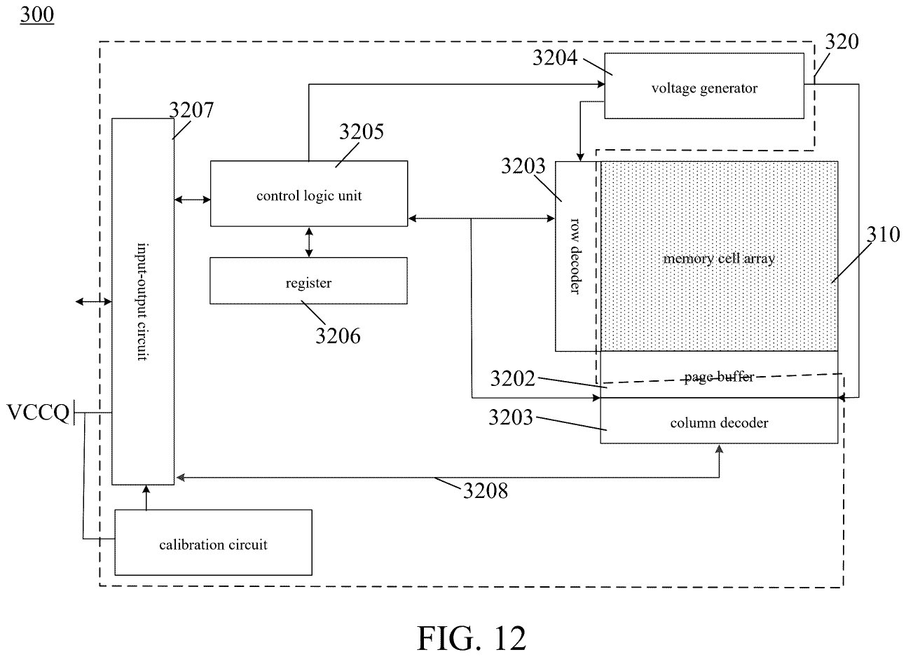

As shown in FIG. 12, the peripheral circuit 320 comprises various types of circuit structures formed using metal-oxide-semiconductor (MOS) transistors. For example, taking the memory cell array 310 being NAND memory cell array as an example, as shown in FIG. 12, the peripheral circuit 320 may comprise a plurality of circuit structures such as a row decoder/word line driver 3201, a page buffer (PB)/sense amplifier 3202, a column decoder/bit line driver 3203, a voltage generator 3204, a control logic unit 3205, a latch circuit 3206, an interface 3207, and a data bus 3208.

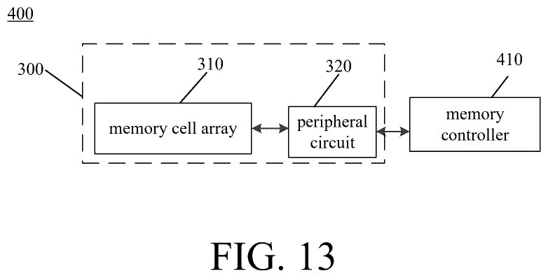

As shown in FIG. 12 and FIG. 13, the peripheral circuit 320 may be coupled to the memory cell array 310 through a bit line (BL), a word line (WL), a source line, a source select gate (SSG), and a drain select gate (DSG). The peripheral circuit 320 is configured to implement logical operations (e.g., program, read, or write operations) of the memory cell array 310 by applying at least one of a voltage signal and a current signal to each target memory cell through a bit line BL, a word line WL, a source line SL, a source select gate SSG or a drain select gate DSG, or the like, and sensing at least one of a voltage signal and a current signal from each target memory cell.

As shown in FIG. 11, based on the structure and connection relationship of the above memory cell array 310 and the peripheral circuit 320, the peripheral circuit 320 comprises a first voltage receiving terminal 321, a second voltage receiving terminal 322, an input-output circuit 200 and a calibration circuit 100.

The first voltage receiving terminal 321 is coupled to an external power supply. For example, the first voltage receiving terminal 321 may be an interface or pin which is a signal terminal capable of transmitting the power supply voltage signal VCCQ of the external power supply. An external power supply may refer to a power supply provided externally to an integrated circuit (IC) or an electronic device. For example, the external power source may refer to a power source provided by a battery, a power adapter, a power line, or a power module, which is not limited in the examples according to the present disclosure.

The second voltage receiving terminal 322 is coupled to an external power supply. For example, the second voltage receiving terminal 322 may be an interface or pin which is a signal terminal capable of transmitting the power supply voltage signal VCCQ of the external power supply.

The input-output circuit 200 is coupled to the first voltage receiving terminal 321, and is configured to receive the power supply voltage signal VCCQ transmitted by the external power supply, and output data in the memory cell array 310 or input data to the memory cell array 310 in response to the control signal.

The calibration circuit 100 is coupled to the second voltage receiving terminal 322 and the input-output circuit 200, and is configured to receive the power supply voltage signal VCCQ and output the calibrated power supply voltage signal ZQ_code based on the power supply voltage signal VCCQ; and output the calibrated power supply voltage signal V_ZQ using the processed power supply voltage signal in response to the first driving signal EN1, and output the impedance calibration code ZQ_code to the input-output circuit 200 based on the calibrated power supply voltage signal V_ZQ, to calibrate the input impedance and the output impedance of the input-output circuit 200.

For example, as shown in FIG. 2 and FIG. 11, the input-output circuit 200 and the calibration circuit 100 may respectively receive the power supply voltage signal VCCQ transmitted by the same external power supply, and both the input-output circuit 200 and the calibration circuit 100 are operable to work simultaneously, so that the work efficiency of the data interaction and calibration can be improved, the time consumption caused by the fact that the calibration circuit and the input-output circuit cannot work simultaneously is reduced, and the efficiency of the data interaction is improved. The logic of the calibration by calibration circuit 100 may refer to the above example, and details are not described herein again.

Moreover, since the calibration circuit 100 itself may determine, based on the acquired power supply voltage signal VCCQ, an independent internal power supply that drives the calibration sub-circuit 120 to perform the calibration operation, the voltage that drives the calibration circuit 100 is not affected by external other circuits (noise or charge loss), which helps to improve the stability of driving the calibration circuit 100 to perform the calibration operation and improve the accuracy of the calibration.

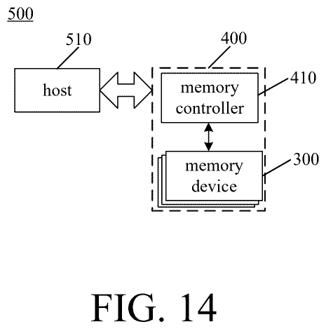

In some examples, as shown in FIG. 13, the present disclosure provides a memory system 400. The memory system 400 comprises one or more memory devices 300 (see FIG. 14) and a memory controller 410. The memory controller 410 is coupled to one or more memory devices 300 and is configured to control the memory device 300.

The memory device 300 comprises a calibration circuit 100 and an input-output circuit 200; and at least one of the calibration circuits 100 and the input-output circuits 200 of the plurality of memory devices 300 are operable to work simultaneously.

For example, as shown in FIG. 2, FIG. 12 and FIG. 13, a memory device 300 comprises a calibration circuit 100 and an input-output circuit 200. A memory device 300 may perform input impedance calibration or output impedance calibration on the input-output circuit 200 through the calibration circuit 100 while performing data interaction through the input-output circuit 200.

For example, since the input-output circuit 200 and the calibration circuit 100 in each memory device 300 respectively utilize a power supply voltage signal VCCQ, it is unnecessary to exit the I/O read and write operation on the bus, that is, the noise generated by the I/O read and write operation of the input-output circuit 200 would not affect the quality of the power supply signal that drives the calibration circuit 100, and the adverse effect of noise on the bus and the power line on the calibration circuit 100 can be reduced.

In addition, in the circuit structure in which a memory controller 410 controls the plurality of memory devices 300 shown in FIG. 14, the plurality of memory devices may respectively receive power supply voltage signals, wherein the input-output circuit 200 and the calibration circuit 100 in each memory device 300 respectively utilize one power supply voltage signal VCCQ. In this way, at least one of the input-output circuit 200 and the calibration circuit 100 in different memory devices 300 are operable to work simultaneously, which can further reduce the time consumption of the calibration operation on the data interaction, especially in the case that a plurality of memory devices 300 can work simultaneously, the speed of data interaction can be significantly improved.

In some examples, as shown in FIG. 14, an example of the present disclosure illustrates an electronic device 500. For example, the electronic device 500 may comprise, but is not limited to, a mobile phone, a desktop computer, a laptop computer, a tablet computer, a vehicle computer, a game console, a printer, a positioning device, a wearable electronic device, a smart sensor, a virtual reality (VR) device, an augmented reality (AR) device, or any other suitable electronic device having a memory device 300 therein.

With continued reference to FIG. 14, the electronic device 500 may comprise a host 510 and a memory system 400.

The host 510 may be a processor (for example, a central processing unit (CPU) or a system on chip (SoC) (for example, an application process (AP)) of the electronic device 500. The host 510 may be configured to send data to or receive data from the memory system 400.

The memory system 400 comprises a memory controller 410 and one or more memory devices 300, and other integrated circuit structures for signal transmission. The memory controller 410 and the one or more memory devices 300 may be integrated and packaged in a same storage medium. In this way, it helps to apply the memory system 400 to different types of end electronic products.

In view of this, examples of the present disclosure provide a calibration circuit, a calibration method thereof, a memory device, and a memory system, which can improve the accuracy and efficiency of calibration, and reduce time consumption of calibration operations on data interaction.

According to a first aspect, some examples of the present disclosure provide a calibration circuit. The calibration circuit comprises a calibration power management circuit and a calibration sub-circuit. The calibration power management circuit is configured to receive a power supply voltage signal and output a calibrated power supply voltage signal based on the power supply voltage signal. The calibration sub-circuit is coupled to the calibration power management circuit and is configured to generate an impedance calibration code using the calibrated power supply voltage signal in response to a first driving signal.

In some examples, the calibration power management circuit comprises a control circuit and a voltage generation circuit. The control circuit is configured to receive and process the power supply voltage signal and output a voltage calibration code. The voltage generation circuit is configured to acquire the voltage calibration code in response to the first driving signal and output the calibrated power supply voltage signal according to the voltage calibration code.

In some examples, the control circuit comprises a voltage comparison processing circuit and a first register circuit. The voltage comparison processing circuit is configured to compare a reference voltage and the power supply voltage signal in response to a second driving signal and output the voltage calibration code. The first register circuit is coupled to the voltage comparison processing circuit and is configured to store the voltage calibration code.

In some examples, the voltage comparison processing circuit is configured to acquire the power supply voltage signal at a first preset time interval, and respond to the second driving signal when a difference between two acquired adjacent power supply voltage signals is greater than a first threshold.

And/or, the voltage comparison processing circuit is further configured to acquire a temperature of the calibration circuit at a second preset time interval, and respond to the second driving signal when a variation between two adjacent temperatures is greater than a second threshold.

In some examples, the voltage comparison processing circuit is further configured to acquire the power supply voltage signal when the calibration circuit is powered on, process the power supply voltage signal in response to the second driving signal, and output the voltage calibration code.

In some examples, the voltage generation circuit comprises a second register circuit. The second register circuit is coupled to the first register circuit, and is configured to acquire and store the voltage calibration code in the first register circuit in response to the first driving signal.

In some examples, the control circuit comprises an analog-to-digital converter; and the analog-to-digital converter comprises the voltage comparison processing circuit and the first register circuit. And/or, the voltage generation circuit further comprises a low dropout linear regulator or a DC to DC regulator.

In some examples, the calibration sub-circuit comprises a ZQ impedance calibration circuit.

In some examples, the calibration sub-circuit is coupled to the input-output circuit, and is configured to output the impedance calibration code to the input-output circuit in response to the first driving signal, and calibrate an input impedance and an output impedance of the input-output circuit.

In the above calibration circuit, the calibration power management circuit receives the power supply voltage signal, rather than the received power supply signal transmitted to the calibration circuit by another circuit (for example, an input-output circuit) in some examples, the power supply voltage signal that drives the calibration circuit in the present disclosure is not affected by the noise on other signal lines, in turn, the power supply signal (that is, the calibrated power supply voltage signal) that drives the calibration sub-circuit to perform the calibration operation does not have an error or has a negligible error. In this way, the impedance calibration code generated by the calibration sub-circuit by using the calibrated power supply voltage signal is more accurate, and the accuracy of the impedance calibration by the calibration circuit can be improved.

In addition, in some examples, the input-output circuit performs the data interaction operation by using the power supply voltage signal, the voltage that drives the calibration circuit is transmitted by the input-output circuit, and the input-output circuit does not perform data interaction when the calibration circuit performs the calibration operation, the calibration circuit provided in the present disclosure directly uses the power supply voltage signal, that is, the calibration circuit and the input-output circuit provided in the present disclosure receive the power supply voltage signal respectively, both of which are operable to work simultaneously, the work efficiency of data interaction and calibration can be improved, the time consumption caused by the fact that the calibration circuit and the input-output circuit cannot work simultaneously is reduced, and the efficiency of data interaction is improved.

According to a second aspect, some examples of the present disclosure provide a memory device. The memory device comprises a memory cell array and a peripheral circuit. The peripheral circuit is coupled to the memory cell array.

The peripheral circuit comprises a first voltage receiving terminal, a second voltage receiving terminal, an input-output circuit and a calibration circuit. The first voltage receiving terminal is coupled to an external power supply. The second voltage receiving terminal is coupled to the external power supply.

The input-output circuit is coupled to the first voltage receiving terminal, and is configured to receive a power supply voltage signal transmitted by the external power supply, and output data within the memory cell array or input data to the memory cell array in response to a control signal.

The calibration circuit is coupled to the second voltage receiving terminal and the input-output circuit, and is configured to receive the power supply voltage signal and output a calibrated power supply voltage signal based on the power supply voltage signal; and output a calibrated power supply voltage signal by using the processed power supply voltage signal in response to a first driving signal, and output an impedance calibration code to the input-output circuit based on the calibrated power supply voltage signal to calibrate an input impedance and an output impedance of the input-output circuit.

In some examples, the memory device comprises an array of NAND memory cells or an array of DRAM memory cells.

The above memory device comprises the calibration circuit according to any one of the above examples. The beneficial effects of the memory device are the same as the beneficial effects of the calibration circuit according to any one of the above examples, and details are not described herein again.

According to a third aspect, some examples of the present disclosure provide a memory system. The memory system comprises one or more memory devices, and a memory controller. The memory controller is coupled to the one or more memory devices, and is configured to control the memory device.

The memory device comprises a calibration circuit and an input-output circuit; and at least one of the calibration circuits and the input-output circuits of a plurality of memory devices are operable to work simultaneously.

The beneficial effects of the above memory system are the same as the beneficial effects of the memory device provided in any one of the above examples, and details are not described herein again.

According to a fourth aspect, some examples of the present disclosure provide a calibration method of a calibration circuit. The calibration method comprises: receiving and processing a power supply voltage signal.

In response to a first driving signal, a calibrated power supply voltage signal is output by using the processed power supply voltage signal, and an impedance calibration code is generated by using the calibrated power supply voltage signal.

In some examples, the receiving and processing the power supply voltage signal comprises: acquiring the power supply voltage signal at a first preset time interval, and determining whether a voltage difference between two adjacent power supply voltage signals is greater than a first threshold; and if yes, outputting a voltage recording command. And/or, acquiring temperature of a region where the calibration circuit is located at a second preset time interval, and determining whether a variation between two adjacent temperatures is greater than a second threshold; and if yes, outputting a voltage recording command;
generating a second driving signal in response to the voltage recording command;
outputting and storing a voltage calibration code based on the currently acquired power supply voltage signal in response to the second driving signal.

In some examples, the receiving and processing the power supply voltage signal comprises: acquiring a voltage used at the time of power-on as the power supply voltage signal in response to a power-on instruction. Comparing a reference voltage with the power supply voltage signal in response to the second driving signal, and outputting and storing the voltage calibration code.

In some examples, the outputting the calibrated power supply voltage signal by using the processed power supply voltage signal in response to the first driving signal comprises: acquiring the voltage calibration code by using a voltage generation circuit in response to the first driving signal, and outputting the calibrated power supply voltage signal according to the voltage calibration code. A voltage value of the calibrated power supply voltage signal is equal to a voltage value of the power supply voltage signal.

In some examples, in response to the first driving signal, the voltage calibration code in a first register is acquired by using the voltage generation circuit and the acquired voltage calibration code is stored to a second register. The calibrated power supply voltage signal is outputted by using the voltage calibration code of the second register, and a calibration sub-circuit uses the calibrated power supply voltage signal to generate an impedance calibration code and performs an impedance calibration operation.

In some examples, during an impedance calibration operation performed by the calibration sub-circuit, a calibration power management circuit updates the voltage calibration code stored in a first register circuit of the control circuit in response to a plurality of second driving signals, respectively.

In some examples, the calibration method further comprises: acquiring, by the calibration sub-circuit, the current first driving signal based on an ending of the previous impedance calibration operation, and generating an impedance calibration code of a current operation in response to the current first driving signal.

In some examples, the calibration method further comprises: continuing to perform operations prior to the calibration of the memory device in response to a resume operation instruction based on the ending of the impedance calibration operation.

In some examples, the memory device comprises a plurality of memory devices, each of the memory devices comprising the calibration circuit and the input-output circuit that acquire a power supply voltage signal of an external power supply from different voltage receiving terminals.

The calibration method further comprises: performing, by the plurality of memory devices, an input impedance calibration or an output impedance calibration of the plurality of input-output circuits by using the calibrated power supply voltage signal simultaneously in response to one of the first driving signals, respectively. The input-output circuit and the calibration circuit are operable to work simultaneously.

The above calibration method is configured to drive the calibration circuit according to any one of the above examples. The beneficial effects of the calibration method of the calibration circuit are the same as the beneficial effects of the calibration circuit according to any one of the above examples, and details are not described herein again.

The above descriptions are only specific implementations of the present disclosure, but the protection scope of the present disclosure is not limited thereto, and changes or replacements that may be easily conceived by any person skilled in the art within the technical scope of the present disclosure should be covered within the protection scope of the present disclosure.

What is claimed is:

1. A calibration circuit, comprising:
a calibration power management circuit configured to receive a power supply voltage signal and output a calibrated power supply voltage signal based on the power supply voltage signal; and
a calibration sub-circuit coupled to the calibration power management circuit and configured to generate an impedance calibration code using the calibrated power supply voltage signal in response to a first driving signal.

2. The calibration circuit of claim 1, wherein the calibration power management circuit comprises:
a control circuit configured to receive and process the power supply voltage signal and output a voltage calibration code; and
a voltage generation circuit configured to acquire the voltage calibration code in response to the first driving signal and output the calibrated power supply voltage signal according to the voltage calibration code.

3. The calibration circuit of claim 2, wherein the control circuit comprises:
a voltage comparison processing circuit configured to compare a reference voltage and the power supply voltage signal in response to a second driving signal and output the voltage calibration code; and
a first register circuit coupled to the voltage comparison processing circuit and configured to store the voltage calibration code.

4. The calibration circuit of claim 3, wherein the voltage comparison processing circuit is configured to acquire the power supply voltage signal at a first preset time interval, and respond to the second driving signal when a difference between two acquired adjacent power supply voltage signals is greater than a first threshold;
and/or,
the voltage comparison processing circuit is further configured to acquire a temperature of the calibration circuit at a second preset time interval, and respond to the second driving signal when a variation between two adjacent temperatures is greater than a second threshold.

5. The calibration circuit of claim 3, wherein the voltage comparison processing circuit is further configured to acquire the power supply voltage signal when the calibration circuit is powered on, process the power supply voltage signal in response to the second driving signal, and output the voltage calibration code.

6. The calibration circuit of claim 3, wherein the voltage generation circuit comprises a second register circuit;
the second register circuit is coupled to the first register circuit, and is configured to acquire and store the voltage calibration code in the first register circuit in response to the first driving signal.

7. The calibration circuit of claim 6, wherein the control circuit comprises an analog-to-digital converter; and the analog-to-digital converter comprises the voltage comparison processing circuit and the first register circuit;
and/or,
the voltage generation circuit further comprises a low dropout linear regulator or a DC to DC regulator.

8. The calibration circuit of claim 1, wherein the calibration sub-circuit comprises a ZQ impedance calibration circuit.

9. The calibration circuit of claim 1, wherein the calibration sub-circuit is coupled to an input-output circuit, and is configured to output the impedance calibration code to the input-output circuit in response to the first driving signal, and calibrate an input impedance and an output impedance of the input-output circuit.

10. A memory device, comprising:
a memory cell array; and
a peripheral circuit coupled to the memory cell array; the peripheral circuit comprises:
a first voltage receiving terminal coupled to an external power supply;
a second voltage receiving terminal coupled to the external power supply;
an input-output circuit coupled to the first voltage receiving terminal, and configured to receive a power supply voltage signal transmitted by the external power supply, and output data within the memory cell array or input data to the memory cell array in response to a control signal; and
a calibration circuit coupled to the second voltage receiving terminal and the input-output circuit, and configured to receive the power supply voltage signal and output a calibrated power supply voltage signal based on the power supply voltage signal; and output a calibrated power supply voltage signal by using the processed power supply voltage signal in response to a first driving signal, and output an impedance calibration code to the input-output circuit based on the calibrated power supply voltage signal to calibrate an input impedance and an output impedance of the input-output circuit.

11. The memory device of claim 10, comprising an array of NAND memory cells or an array of DRAM memory cells.

12. A calibration method of a calibration circuit, comprising:
receiving and processing a power supply voltage signal; and
outputting a calibrated power supply voltage signal by using the processed power supply voltage signal in response to a first driving signal, and generating an impedance calibration code by using the calibrated power supply voltage signal.

13. The calibration method of claim 12, wherein the receiving and processing the power supply voltage signal comprises:
acquiring the power supply voltage signal at a first preset time interval, and determining whether a voltage difference between two adjacent power supply voltage signals is greater than a first threshold; and if yes, outputting a voltage recording command;
and/or, acquiring a temperature of a region where the calibration circuit is located at a second preset time interval, and determining whether a variation between two adjacent temperatures is greater than a second threshold; and if yes, outputting a voltage recording command;
generating a second driving signal in response to the voltage recording command; and
outputting and storing a voltage calibration code based on the currently acquired power supply voltage signal in response to the second driving signal.

14. The calibration method of claim 13, wherein the receiving and processing the power supply voltage signal comprises:
acquiring a voltage used at the time of power-on as the power supply voltage signal in response to a power-on instruction; and
comparing a reference voltage with the power supply voltage signal in response to the second driving signal, and outputting and storing the voltage calibration code.

15. The calibration method of claim 13, wherein the outputting the calibrated power supply voltage signal by using the processed power supply voltage signal in response to the first driving signal comprises:
acquiring the voltage calibration code by using a voltage generation circuit in response to the first driving signal, and outputting the calibrated power supply voltage signal according to the voltage calibration code; and
wherein a voltage value of the calibrated power supply voltage signal is equal to a voltage value of the power supply voltage signal.

16. The calibration method of claim 15, further comprising in response to the first driving signal, acquiring the voltage calibration code in a first register and storing the acquired voltage calibration code to the second register by using the voltage generation circuit; and
outputting the calibrated power supply voltage signal by using the voltage calibration code of the second register, and generating an impedance calibration code and performing an impedance calibration operation using the calibrated power supply voltage signal by a calibration sub-circuit.

17. The calibration method of claim 16, wherein during the impedance calibration operation performed by the calibration sub-circuit, a calibration power management circuit updates the voltage calibration code stored in a first register circuit of a control circuit in response to a plurality of second driving signals, respectively.

18. The calibration method of claim 16, further comprising:
acquiring, by the calibration sub-circuit, a current first driving signal based on an ending of a previous impedance calibration operation, and generating an impedance calibration code of a current operation in response to the current first driving signal.

19. The calibration method of claim 18, further comprising:
continuing to perform operations prior to the calibration of a memory device in response to a resume operation instruction based on the ending of the impedance calibration operation.

20. The calibration method of claim 19, wherein the memory device comprises a plurality of memory devices, each of the memory devices comprising the calibration circuit and an input-output circuit that acquire a power supply voltage signal of an external power supply from different voltage receiving terminals;
the calibration method further comprises:
performing, by the plurality of memory devices, an input impedance calibration or an output impedance calibration of a plurality of input-output circuits simultaneously by using the calibrated power supply voltage signal in response to one of the first driving signals, respectively;
wherein the input-output circuit and the calibration circuit are operable to work simultaneously.
